(19) United States
(12) Patent Application Publication
(10) Pub. No.: US 2026/0344160 A1
(43) Pub. Date: Oct. 29, 2026

(54) DISPLAY APPARATUS

(71) Applicant: LG Display Co., Ltd., Seoul (KR)

(72) Inventors: WooSung KIM, Paju-si (KR); Hyunseok NA, Paju-si (KR); Seongsoo CHO, Paju-si (KR); SangHak SHIN, Paju-si (KR)

(21) Appl. No.: 19/659,551

(22) Filed: Apr. 27, 2026

(30) Foreign Application Priority Data
Apr. 29, 2025 (KR) 10-2025-0056063

(51) Int. Cl. H10H 29/851; H10H 29/37; H10H 29/855

(52) U.S. Cl. CPC H10H 29/8514; H10H 29/37; H10H 29/8552

(57) ABSTRACT

A display apparatus includes a substrate, a light-emitting element disposed on the substrate, a light-conversion layer disposed on the light-emitting element, an upper insulating film disposed on the light-conversion layer, and a color filter layer disposed on the upper insulating film, wherein the color filter layer is in direct contact with the upper insulating film.

### CROSS REFERENCE TO RELATED APPLICATION

Pursuant to 35 U.S.C. § 119(a), the present application claims the benefit of an earlier filing date and right of priority to Korean Patent Application No. 10-2025-0056063, filed Apr. 29, 2025, the entire contents of which are incorporated herein for all purposes by this reference.

### TECHNICAL FIELD

The present disclosure relates to a display apparatus.

### BACKGROUND

As the information society develops, various demands for display apparatuses for displaying images are increasing, and various types of display apparatuses, such as a liquid crystal display (LCD) apparatus and an organic light-emitting diode (OLED) display apparatus, are being utilized.

Among the display apparatuses, there is an advantage in that the OLED display apparatus as the self-luminous type has a wider viewing angle and a higher contrast ratio, and can be lighter and thinner and has lower power consumption than the LCD apparatus because it does not require a separate backlight. In addition, there is an advantage in that the OLED display apparatus can drive at a low voltage, have a fast response time, and especially have the inexpensive manufacturing cost.

### SUMMARY

According to one implementation of the present specification, there is provided a display apparatus including a substrate, a light-emitting element disposed on the substrate, a light-conversion layer disposed on the light-emitting element, an upper insulating film disposed on the light-conversion layer, and a color filter layer disposed on the upper insulating film, wherein the color filter layer is in direct contact with the upper insulating film.

According to another implementation of the present specification, there is provided a display apparatus including a substrate on which a first sub-pixel and a second sub-pixel are disposed, light emitting elements including a first light emitting element disposed in the first sub-pixel and a second light emitting element disposed in the second sub-pixel on the substrate, a light-conversion layer disposed on the light-emitting elements and including a first light-conversion layer disposed in the first sub-pixel and a second light-conversion layer disposed in the second sub-pixel, an upper insulating film disposed on the light-conversion layer, a color filter layer disposed on the upper insulating film and including a first color filter layer disposed in the first sub-pixel and a second color filter layer disposed in the second sub-pixel, and a black matrix which is disposed on the upper insulating film, separates the first light-conversion layer from the second light-conversion layer, and separates the first color filter layer from the second color filter layer.

Detailed matters of other implementations are included in the detailed description and accompanying drawings.

According to some implementations of the present specification, it is possible to suppress or prevent color mixing between adjacent pixel (sub-pixels).

According to some implementations of the present specification, it is possible to improve color tone reproducibility.

According to some implementations of the present specification, it is possible to reduce the thickness of the display apparatus.

According to some implementations of the present specification, by preventing color mixing between adjacent sub-pixels, the display apparatus can be driven at a low power level, thereby reducing power consumption.

However, effects obtainable from the present specification are not limited to the above effects, and other effects that are not described will be able to be clearly understood by those skilled in the art to which the present specification pertains based on the following description.

### BRIEF DESCRIPTION OF THE DRAWINGS

FIG. 1 is a plan view of an example of a display apparatus according to one implementation.

FIG. 2 is an enlarged plan view of an example of a pixel of the display apparatus according to one implementation.

FIG. 3 is an example of a cross-sectional view along line A-A′ in FIG. 2.

FIG. 4 is an example of an enlarged view of area Q1 in FIG. 3.

FIGS. 5 to 7 are views illustrating an example of each operation of a process of manufacturing the display apparatus according to one implementation.

FIG. 8 is a cross-sectional view of an example of a display apparatus according to another implementation taken along a line similar to line A-A′ in FIG. 2.

### DETAILED DESCRIPTION

An OLED display apparatus using organic materials can be prone to defective pixels, for example due to oxidation between an organic light-emitting layer and electrodes due to moisture and oxygen penetration.

Such problems can be mitigated by display apparatuses that implement light-emitting diodes (LEDs) using inorganic materials as light-emitting elements. Such light-emitting display apparatuses are attractive options as next-generation display apparatuses because they have high image quality and high reliability.

Implementations of the present disclosure can provide a display apparatus capable of suppressing or preventing color mixing between adjacent pixels (sub-pixels).

Implementations of the present disclosure can also provide a display apparatus capable of improving color tone reproducibility.

Implementations of the present disclosure can also provide a display apparatus with a reduced thickness.

Objects of the present specification are not limited to the above objects, and other technical objects may be inferred from the following implementations.

Hereinafter, implementations will be described with reference to the accompanying drawings. In the specification, when a certain component (or an area, a layer, a portion, etc.) is described as “on,” “connected,” or “coupled to” another component, it means that the certain component may be directly connected/coupled to another component or still another component may be disposed therebetween.

The same reference numerals indicate the same components. In addition, in the drawings, thicknesses, proportions, and dimensions of components are exaggerated for effective description of technical contents. The term “and/or” includes all one or more combinations that may be defined by the associated configurations.

Terms such as “first,” “second,” and the like may be used to describe various components, but the components are not limited by the terms. The terms are used only for the purpose of distinguishing one component from another. For example, a first component may be referred to as a second component, and similarly, the second component may also be referred to as the first component without departing from the scopes of various implementations. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that terms such as “includes” or “has” are intended to specify the presence of features, numbers, steps, operations, components, parts, or a combination thereof described in the specification and does not preclude the presence or addition possibility of one or more other features, numbers, steps, operations, components, parts, or combinations thereof in advance.

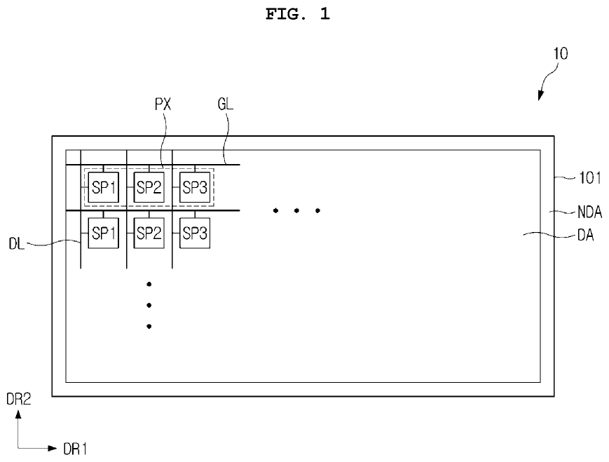

FIG. 1 is a plan view of an example of a display apparatus according to one implementation.

Referring to FIG. 1, a display apparatus 10 according to one implementation of the present specification may be applied to various display environments, such as a TV, a signage, a mobile terminal such as a cell phone or smart phone, a display for a computer, such as a laptop or desktop, a head-up display (HUD) for a vehicle, a display backlight unit, a virtual reality (VR), augmented reality (AR), or mixed reality (MR) display, etc. However, the configuration according to the implementation described herein may be applied to any display-capable apparatus in the same manner even when a new product type is developed in the future.

The display apparatus 10 may use a micro light-emitting diode (LED) as a display element, but is not limited thereto.

The display apparatus 10 may include a flexible display manufactured on a thin, flexible substrate. A flexible display may maintain the characteristics of a flat panel display and may be bent or rolled like paper.

The display apparatus 10 may include a display area DA in which a plurality of pixels PX are disposed, and a non-display area NDA. The display apparatus 10 may include the substrate 101 that provides a support on which the plurality of pixels PX may be disposed.

The display area DA may display images, videos, pictures, etc., and include a plurality of pixels PX. The non-display area NDA does not display a screen and may include, for example, a bezel area. The non-display area NDA may be disposed around the display area DA, but is not limited thereto. The non-display area NDA may be disposed to surround the display area DA, but is not limited thereto.

The non-display area NDA may be defined as an area on the substrate 101 excluding the display area DA and may have a relatively narrow width (or size) compared to the display area DA, but is not limited thereto.

The pixel PX may be composed of a plurality of sub-pixels (SP1, SP2, and SP3), and the sub-pixels (SP1, SP2, and SP3) may emit light of different first, second, and third colors, respectively. For example, the sub-pixels (SP1, SP2, and SP3) may emit red, blue, and green light, respectively. A first sub-pixel SP1 may emit red light, a second sub-pixel SP2 may emit green light, and a third sub-pixel SP3 may emit blue light.

However, various implementations of the present specification are not limited thereto, and the pixel PX may also include sub-pixels that emit light of white, etc. The sub-pixels (SP1, SP2, and SP3) may be sequentially disposed in a first direction DR1.

At least one light-emitting element may be disposed in each of the sub-pixels (SP1, SP2, and SP3).

The pixel PX may be repeatedly disposed in the first direction DR1 and a second direction DR2. Specifically, each of the sub-pixels (SP1, SP2, and SP3) may be alternately disposed in the first direction DR1. Each of the sub-pixels (SP1, SP2, and SP3) may be repeatedly disposed in the second direction DR2.

The display apparatus 10 may further include various signal lines, such as a gate line GL and a data line DL that are electrically connected to the sub-pixels (SP1, SP2, and SP3) of each pixel PX. The gate line GL and the data line DL may provide signals to the sub-pixels (SP1, SP2, and SP3) of each pixel PX.

The gate line GL may extend in the first direction DR1 and may be repeatedly disposed in the second direction DR2. The data line DL may extend in the second direction DR2 and may be repeatedly disposed in the first direction DR1. The gate line GL and the data line DL may intersect each other.

The substrate 101 is an array substrate on which transistors are formed and may be made of a plastic material or glass material.

In one example, the substrate 101 may include an opaque or colored polyimide material. In this case, the display apparatus 10 may further include a back plate coupled to a rear surface of the substrate 101 to maintain the substrate 101 in a flat surface state.

In one example, the back plate may include a plastic material, for example, a polyethylene terephthalate material.

In one example, the substrate 101 may be a glass substrate. For example, the glass substrate 101 may be a thin glass substrate having a thickness of 100 μm or less and may have flexible properties.

In addition, the substrate 101 may be formed by bonding two or more substrates or being divided into two or more layers.

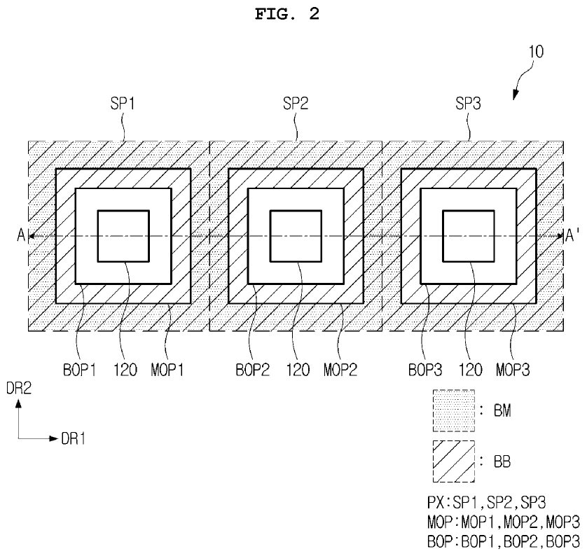

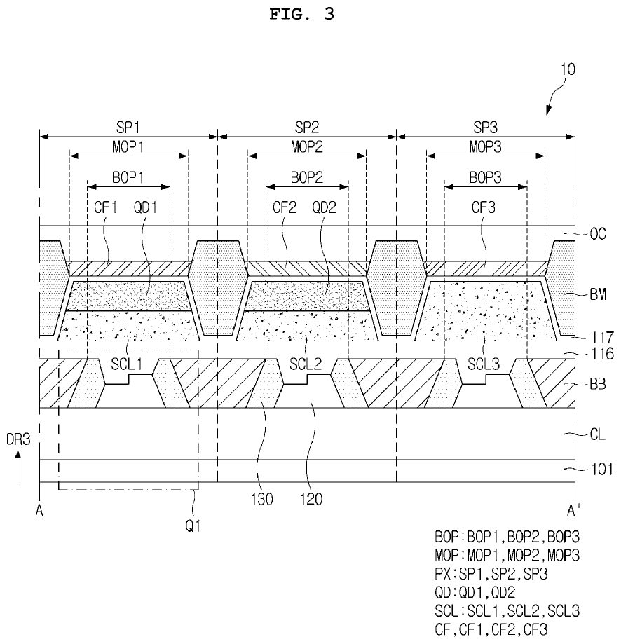

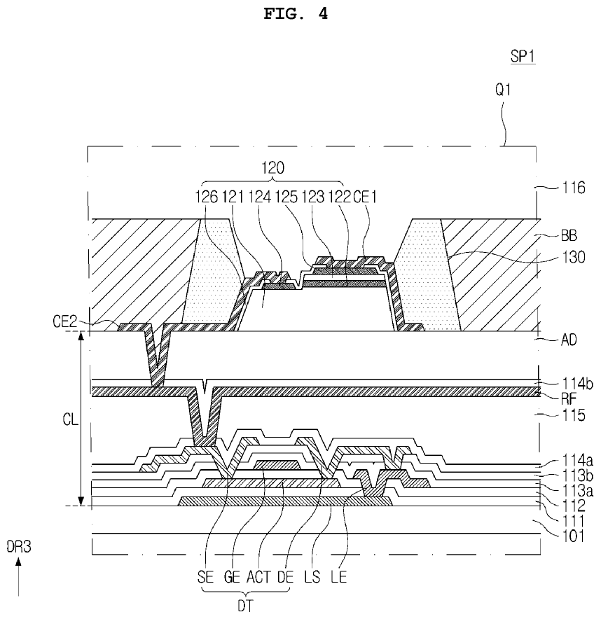

FIG. 2 is an enlarged plan view of a pixel of the display apparatus according to one implementation. FIG. 3 is a cross-sectional view along line A-A′ in FIG. 2. FIG. 4 is an enlarged view of area Q1 in FIG. 3.

In FIG. 4, a circuit layer CL of the first sub-pixel SP1 will be described, and the description thereof may be applied to the second sub-pixel SP2 and the third sub-pixel SP3 in substantially the same manner.

Referring to FIGS. 2 to 4, the display apparatus 10 according to one implementation may include the substrate 101, the circuit layer CL, a light-emitting element 120, a diffusion layer 130, a bank BB, a protective layer 116, a scattering layer SCL, a light-conversion layer QD, an upper insulating film 117, a black matrix BM, a color filter layer CF, and an overcoat layer OC.

The circuit layer CL may include a transistor, which drives the light-emitting element 120, and may also include various signal lines. In addition, a planarization layer and a plurality of insulating layers may be further disposed between components included in the circuit layer CL. The circuit layer CL may be disposed on the substrate 101.

The circuit layer CL may include, for example, a light-shielding layer LS, a buffer layer 111, a driving transistor DT, a gate insulating layer 112, one or more interlayer insulating layers (such as a first interlayer insulating layer 113a and a second interlayer insulating layer 113b), a first passivation layer 114a, a planarization layer 115, a reflective layer RF, and an adhesive layer AD.

The light-shielding layer LS may be disposed on the substrate 101. The light-shielding layer LS may be disposed in each of the plurality of sub-pixels (SP1, SP2, and SP3). The light-shielding layer LS blocks light incident from below the substrate 101 on an active layer ACT of the driving transistor DT, which will be described below. The light-shielding layer LS can block the light incident on the active layer ACT of the driving transistor DT, thereby minimizing leakage current.

The buffer layer 111 is disposed on the substrate 101 and the light-shielding layer LS. The buffer layer 111 can reduce the penetration of moisture or impurities through the substrate 101. The buffer layer 111 may be formed of, for example, a single layer or multiple layers of silicon oxide (SiOₓ) or silicon nitride (SiNₓ), but is not limited thereto. However, the buffer layer 111 may be omitted depending on the type of the substrate 101 or the type of the transistor, but is not limited thereto.

The driving transistor DT is disposed on the buffer layer 111. The driving transistor DT may include the active layer ACT, a gate electrode GE, a source electrode SE, and a drain electrode DE.

The active layer ACT is disposed on the buffer layer 111. The active layer ACT may be made of a semiconductor material such as oxide semiconductor, amorphous silicon, or polysilicon, but is not limited thereto.

The gate insulating layer 112 is disposed on the active layer ACT. The gate insulating layer 112 may electrically insulate the active layer ACT and the gate electrode GE and may be formed of a single layer or multiple layers of silicon oxide (SiOₓ) or silicon nitride (SiNₓ), but is not limited thereto.

The gate electrode GE is disposed on the gate insulating layer 112. The gate electrode GE may be made of a conductive material, such as copper (Cu), aluminum (Al), molybdenum (Mo), nickel (Ni), titanium (Ti), chromium (Cr), or an alloy thereof, but is not limited thereto.

One or more interlayer insulating layers, such as the first interlayer insulating layer 113a and the second interlayer insulating layer 113b, are disposed on the gate electrode GE. The first interlayer insulating layer 113a and the second interlayer insulating layer 113b include contact holes through which the source electrode SE and the drain electrode DE of the driving transistor DT are in contact with the active layer ACT. The first interlayer insulating layer 113a and the second interlayer insulating layer 113b may protect components below the first interlayer insulating layer 113a and the second interlayer insulating layer 113b and may be formed of a single layer or multiple layers of silicon oxide (SiOₓ) or silicon nitride (SiNₓ), but are not limited thereto.

The source electrode SE and the drain electrode DE, which are electrically connected to the active layer ACT, are disposed on the second interlayer insulating layer 113b. The source electrode SE and the drain electrode DE may be made of a conductive material, such as copper (Cu), aluminum (Al), molybdenum (Mo), nickel (Ni), titanium (Ti), chromium (Cr), or an alloy thereof, but are not limited thereto.

In some implementations, the display device can implement the first interlayer insulating layer 113a and the second interlayer insulating layer 113b, that is, a plurality of insulating layers that are disposed between the gate electrode GE and both the source electrode SE and the drain electrode DE. However, implementations are not limited thereto, and for example in some implementations only one insulating layer may be disposed between the gate electrode GE and both the source electrode SE and the drain electrode DE.

In addition, as illustrated in the drawings, when the plurality of insulating layers, such as the first interlayer insulating layer 113a and the second interlayer insulating layer 113b, are disposed between the gate electrode GE and both the source electrode SE and the drain electrode DE, an electrode may be additionally formed between the first interlayer insulating layer 113a and the second interlayer insulating layer 113b, and the additionally formed electrode may form a capacitor with another component disposed below the first interlayer insulating layer 113a or above the second interlayer insulating layer 113b.

An auxiliary electrode LE is disposed on the gate insulating layer 112. The auxiliary electrode LE electrically connects the light-shielding layer LS below the buffer layer 111 to one of the source electrode SE and the drain electrode DE on the second interlayer insulating layer 113b. For example, the light-shielding layer LS may be electrically connected to one of the source electrode SE or the drain electrode DE through the auxiliary electrode LE so as not to function as a floating gate, thereby minimizing fluctuations in a threshold voltage of the driving transistor DT caused by the floating light-shielding layer LS. In the drawings, the light-shielding layer LS is illustrated as being connected to the drain electrode DE, but may also be connected to the source electrode SE, and is not limited thereto.

The first passivation layer 114a is disposed on the driving transistor DT. The first passivation layer 114a may protect components under the first passivation layer 114a and may be formed of a single layer or multiple layers of silicon oxide (SiOₓ) or silicon nitride (SiNₓ), but is not limited thereto.

The planarization layer 115 is disposed on the first passivation layer 114a. The planarization layer 115 may planarize an upper structure on the substrate 101 on which the driving transistor DT is disposed and has a flat upper surface. The planarization layer 115 may be formed of a single layer or multiple layers and may be made of, for example, a photoresist or an acryl-based organic material, but is not limited thereto.

The reflective layer RF is disposed on the planarization layer 115. The reflective layer RF may electrically connect the light-emitting element 120 to the driving transistor DT and simultaneously reflect light emitted from the light-emitting element 120 upward from the light-emitting element 120. The reflective layer RF may be made of a conductive material with excellent reflective properties and may reflect light emitted from the light-emitting element 120 upward from the light-emitting element 120.

A second passivation layer 114b is disposed on the reflective layer RF. For example, the second passivation layer 114b is an insulating layer for protecting components under the second passivation layer 114b and may be formed of a single layer or multiple layers of silicon oxide (SiOₓ) or silicon nitride (SiNₓ), but is not limited thereto.

The adhesive layer AD is disposed on the second passivation layer 114b. The adhesive layer AD may be coated on a front surface of the substrate 101 to fix the light-emitting element 120 disposed on the adhesive layer AD. The adhesive layer AD may be made of a photocurable adhesive material which may be cured by light. For example, the adhesive layer AD may be made of an acrylic-based material containing a photosensitive agent, but is not limited thereto.

A plurality of light-emitting elements 120 are disposed on the adhesive layer AD. The light-emitting element 120 may be disposed in each of the plurality of sub-pixels. The plurality of light-emitting elements 120 may emit light by current and include the light-emitting elements 120 that emit red light, green light, blue light, etc., and combinations of these elements may emit light of various colors including white. For example, the plurality of light-emitting elements 120 may be light-emitting diodes (LEDs) or micro LEDs that emit light through inorganic materials, that is, the light-emitting diode may include an inorganic film for emitting light, but are not limited thereto.

The light-emitting element 120 may include a first semiconductor layer 121, a light-emitting layer 122, a second semiconductor layer 123, a first electrode 124, a second electrode 125, and an encapsulating film 126.

The first semiconductor layer 121 is disposed on the adhesive layer AD, and the second semiconductor layer 123 is disposed on the first semiconductor layer 121. The first semiconductor layer 121 and the second semiconductor layer 123 may be made of specific materials doped with n-type and p-type impurities, respectively.

For example, the first semiconductor layer 121 and the second semiconductor layer 123 may have materials, such as gallium nitride (GaN), indium aluminum phosphide (InAlP), or gallium arsenide (GaAs), doped with n-type and p-type impurities, respectively. In addition, the p-type impurity may be magnesium, zinc (Zn), beryllium (Be), etc., and the n-type impurity may be silicon (Si), germanium, tin (Sn), etc., but various implementations of the present specification are not limited thereto.

The light-emitting layer 122 is disposed between the first semiconductor layer 121 and the second semiconductor layer 123. The light-emitting layer 122 may emit light by receiving holes and electrons from the first semiconductor layer 121 and the second semiconductor layer 123. The light-emitting layer 122 may be formed in a single-layer or multi-quantum well (MQW) structure and may be made of, for example, indium gallium nitride (InGaN), gallium nitride (GaN), etc., but is not limited thereto.

The first electrode 124 is disposed on the first semiconductor layer 121. The first electrode 124 electrically connects the driving transistor DT to the first semiconductor layer 121. The first electrode 124 may be disposed on an upper surface of the first semiconductor layer 121 exposed from the light-emitting layer 122 and the second semiconductor layer 123. The first electrode 124 may be made of a conductive material, for example, a transparent conductive material, such as ITO or IZO, titanium (Ti), gold (Au), silver (Ag), copper (Cu), or an alloy thereof, but is not limited thereto.

The second electrode 125 is disposed on the second semiconductor layer 123. The second electrode 125 may be disposed on an upper surface of the second semiconductor layer 123. The second electrode 125 electrically connects a power supply line to the second semiconductor layer 123. The second electrode 125 may be made of a conductive material, for example, a transparent conductive material, such as ITO or IZO, titanium (Ti), gold (Au), silver (Ag), copper (Cu), or an alloy thereof, but is not limited thereto.

An encapsulation film 126 may be disposed that surrounds the first semiconductor layer 121, the light-emitting layer 122, the second semiconductor layer 123, the first electrode 124, and the second electrode 125. The encapsulation film 126 may be made of an insulation material and can protect the first semiconductor layer 121, the light-emitting layer 122, and the second semiconductor layer 123. In addition, contact holes for exposing the first electrode 124 and the second electrode 125 may be formed in the encapsulation film 126 so that a first connection electrode CE1 and the second electrode 125 may be electrically connected, and a second connection electrode CE2 and the first electrode 124 may be electrically connected.

The first connection electrode CE1 is disposed on the adhesive layer AD and the light-emitting element 120. One end of the first connection electrode CE1 may be electrically connected in contact with the second electrode 125 exposed by the encapsulation film 126. Although not illustrated, the other end of the first connection electrode CE1 may be electrically connected to the power supply line.

The second connection electrode CE2 is disposed on the adhesive layer AD and the light-emitting element 120. One end of the second connection electrode CE2 may be electrically connected in contact with the first electrode 124 exposed by the encapsulation film 126. The other end of the second connection electrode CE2 may be electrically connected in contact with the reflective layer RF via a contact hole formed within the adhesive layer AD and the second passivation layer 114b.

The reflective layer RF may be electrically connected to the driving transistor DT through contact with the source electrode SE of the driving transistor DT via a contact hole formed within the planarization layer 115. As such, through the reflective layer RF, the second connection electrode CE2 may be electrically connected to the driving transistor DT, and the first electrode 124 may be electrically connected to the driving transistor DT.

The bank BB may be disposed around the light-emitting element 120. The bank BB may be disposed on the adhesive layer AD. The bank BB may be disposed to surround the light-emitting element 120. The bank BB may be disposed to be spaced a predetermined distance from the light-emitting element 120.

The bank BB may define various bank openings BOP (e.g., BOP1, BOP2, BOP3). The bank openings BOP may expose the light-emitting elements 120 and portions of the adhesive layer AD in the sub-pixels (e.g., SP1, SP2, and SP3).

For example, in the first sub-pixel SP1, a first bank opening BOP1 may expose a portion of the adhesive layer AD, and the light-emitting element 120 may be disposed on the portion of the adhesive layer AD exposed by the first bank opening BOP1. In the second sub-pixel SP2, a second bank opening BOP2 may expose a portion of the adhesive layer AD, and the light-emitting element 120 may be disposed on the portion of the adhesive layer AD exposed by the second bank opening BOP2. In the third sub-pixel SP3, a third bank opening BOP3 may expose a portion of the adhesive layer AD, and the light-emitting element 120 may be disposed on the portion of the adhesive layer AD exposed by the third bank opening BOP3.

In some implementations, sidewalls of the bank BB may be formed in an inverse-taper shape. In such scenarios, the light emitted from the light-emitting element 120 can be suppressed or prevented from leaking into adjacent sub-pixels (SP1, SP2, and SP3). Accordingly, high color reproduction is possible and light leakage defects can be suppressed or prevented.

The bank BB may be made of an opaque material to reduce color mixing between the plurality of sub-pixels and for example, may be made of a black resin, but is not limited thereto.

The diffusion layer 130 may be disposed between the bank BB and the light-emitting element 120. The diffusion layer 130 may be disposed inside the bank openings BOP (BOP1, BOP2, BOP3). The diffusion layer 130 may be disposed around each light-emitting element 120. The diffusion layer 130 may be disposed to surround the light-emitting element 120. Accordingly, the bank BB may be disposed to surround the light-emitting element 120 and the diffusion layer 130.

The diffusion layers 130 disposed around the light-emitting element 120 in each of the sub-pixels (SP1, SP2, and SP3) may be separated and spaced apart from each other.

The diffusion layer 130 may be disposed to expose an upper portion of the light-emitting element 120, but is not limited thereto. The diffusion layer 130 may be disposed on the same layer as the light-emitting element 120. For example, both the diffusion layer 130 and the light-emitting element 120 may be disposed on the adhesive layer AD and may be in direct contact with the adhesive layer AD, but are not limited thereto.

The diffusion layer 130 may be selectively made of at least one of an organic compound containing TiOₓ added to Si—H—O in which a plurality of fine metal particles are dispersed and diffused, a material including a photoactive compound (PAC) and polyimide (PI), a sidewall diffuser from which TiOₓ has been removed, and an insulation material including SiOₓ and SiN.

The diffusion layer 130 may reflect, refract, scatter, and diffract the light emitted from the light-emitting element 120, thereby improving the light output efficiency of the light-emitting element 120.

The protective layer 116 may be disposed on the light-emitting element 120, the diffusion layer 130, and the bank BB. The protective layer 116 can protect components below the protective layer 116 and may be formed of a single layer or multiple layers made of a translucent epoxy, silicon oxide (SiOₓ), or silicon nitride (SiNₓ), but is not limited thereto.

The scattering layers SCL (SCL1, SCL2, SCL3) may be disposed on the light-emitting element 120, and the light-conversion layers QD (QD1, QD2) may be disposed on the scattering layers SCL.

The scattering layers SCL (SCL1, SCL2, SCL3) may scatter the light emitted from the light-emitting element 120. The scattering layers SCL (SCL1, SCL2, SCL3) may include scattering particles that scatter light. The scattering particles may be made of titanium dioxide (TiO₂), but are not limited thereto.

For example, the scattering layers SCL (SCL1, SCL2, SCL3) may scatter anisotropic light incident on the scattering layers SCL (SCL1, SCL2, SCL3) into isotropic light. The anisotropic light is light whose intensity varies depending on the direction. In addition, the isotropic light is light whose intensity is uniform in all directions.

The scattering particles included in the scattering layers SCL (SCL1, SCL2, SCL3) may convert the anisotropic light generated from the light-emitting element 120 incident on the scattering layers SCL (SCL1, SCL2, SCL3) into isotropic light. The light generated from the light-emitting element 120 may be anisotropic light whose intensity varies depending on the direction. The anisotropic light may be incident on the scattering layers SCL (SCL1, SCL2, SCL3), scattered by the scattering layers SCL (SCL1, SCL2, SCL3), and converted into isotropic light whose intensity does not vary depending on the direction.

In some implementations, a first scattering layer SCL1 may be disposed in the first sub-pixel SP1, a second scattering layer SCL2 may be disposed in the second sub-pixel SP2, and a third scattering layer SCL3 may be disposed in the third sub-pixel SP3. The first to third scattering layers SCL1, SCL2, and SCL3 may be separated and spaced apart from each other. The upper insulating film 117 and the black matrix BM may be disposed between the first to third scattering layers SCL1, SCL2, and SCL3. The black matrix BM may be disposed in the area in which the first to third scattering layers SCL1, SCL2, and SCL3 are spaced apart from each other.

A first light-conversion layer QD1 may be disposed on the first scattering layer SCL1, and a second light-conversion layer QD2 may be disposed on the second scattering layer SCL2. A separate light-conversion layer may not be disposed on the third scattering layer SCL3. The first light-conversion layer QD1 may be disposed in the first sub-pixel SP1, and the second light-conversion layer QD2 may be disposed in the second sub-pixel SP2. The present disclosure is not limited to the implementations as described and shown above, and a separate light-conversion layer may be disposed in the third sub-pixel SP3 according to another implementation.

The light-conversion layers QD (QD1, QD2) may convert the light emitted from the light-emitting element 120 into light of the color corresponding to each of the sub-pixels (SP1, SP2, and SP3).

For example, when the first sub-pixel SP1 emits red light, the second sub-pixel SP2 emits green light, the third sub-pixel SP3 emits blue light, and the light-emitting element 120 emits blue light, the first light-conversion layer QD1 may be disposed in the first sub-pixel SP1 and may convert blue light into red light, and the second light-conversion layer QD2 may be disposed in the second sub-pixel SP2 and may convert blue light into green light. In this case, since the third sub-pixel SP3 emits blue light, a separate light-conversion layer may not be disposed, but is not limited thereto.

In some implementations, a thickness of the third scattering layer SCL3 in a thickness direction (third direction DR3) may be greater than those of the first scattering layer SCL1 and the second scattering layer SCL2.

In some implementations, the light-conversion layers QD (QD1, QD2) may include quantum dots of different sizes and types capable of converting the light emitted from the light-emitting element 120 into light of the color corresponding to each of the sub-pixels (SP1, SP2, and SP3). For example, the light-conversion layer QD may include a single-layer quantum dot including one or more of a Group III-V semiconductor nanocrystal and a Group II-VI semiconductor nanocrystal, or a multi-layer quantum dot having a core/shell structure. However, various implementations of the present specification are not limited thereto, and the type of quantum dots included in the light-conversion layer QD is not particularly limited.

The quantum dots are nanoparticles that exhibit photoluminescence, in which electrons excited to a high energy level by external light return to a lower energy level to emit light. Such a characteristic of quantum dots may be used to convert a wavelength (color) of light emitted from a light source in a display apparatus.

The upper insulating film 117 may be disposed on the scattering layer SCL and the light-conversion layer QD. The upper insulating film 117 may cover upper and side surfaces of the scattering layers SCL (SCL1, SCL2, SCL3) and the light-conversion layers QD (QD1, QD2). The upper insulating film 117 may be disposed to separate the scattering layers SCL (SCL1, SCL2, SCL3) and the light-conversion layers QD (QD1, QD2), which are disposed in each of the sub-pixels (SP1, SP2, and SP3).

The upper insulating film 117 may be disposed between the scattering layers SCL (SCL1, SCL2, SCL3) and the light-conversion layers QD (QD1, QD2), which are disposed in each of the sub-pixels (SP1, SP2, and SP3), and may be in direct contact with the protective layer 116 between the scattering layers SCL.

The upper insulating film 117 can suppress or prevent out-gas generated from the light-conversion layer QD from being discharged to the outside. The upper insulating film 117 may be made of an inorganic material, such as silicon nitride (SiNₓ), silicon oxide (SiOₓ), silicon oxynitride (SiOₓN_{y}), etc., but is not limited thereto.

The upper insulating film 117 may be formed of a single layer or multiple layers.

The black matrix BM may be disposed on the upper insulating film 117. The black matrix BM may be disposed at boundaries and peripheries of the sub-pixels (SP1, SP2, and SP3). The black matrix BM may be disposed between each of the scattering layers SCL (SCL1, SCL2, and SCL3) and each of the light-conversion layers QD (QD1 and QD2).

The black matrix BM may fill spaced areas between the first to third scattering layers SCL1, SCL2, and SCL3, thereby preventing light leakage between the sub-pixels (SP1, SP2, and SP3).

The black matrix BM is a black insulating layer and may include black pigments and dyes, etc., but is not limited thereto. The black matrix BM may be disposed at the boundaries and peripheries of the sub-pixels (SP1, SP2, and SP3), thereby suppressing or preventing color mixing between adjacent sub-pixels (SP1, SP2, and SP3) and light leakage.

The black matrix BM can define matrix openings MOP (MOP1, MOP2, MOP3) that expose the upper insulating film 117.

A thickness of the black matrix BM may be greater than a thickness of the scattering layer SCL and the light-conversion layer QD. In some implementations, the thickness of the black matrix BM may be greater than the combined thickness of the first scattering layer SCL1 and the first light-conversion layer QD1, greater than the combined thickness of the second scattering layer SCL2 and the second light-conversion layer QD2, and greater than the thickness of the third scattering layer SCL3. Here, the thickness of each component may refer to a width in the thickness direction (third direction DR3).

The black matrix BM may fill spaces between the first to third scattering layers SCL1, SCL2, and SCL3, and even when filling a space between the first and second light-conversion layers QD1 and QD2, a height of an upper surface of the black matrix BM may be greater than those of upper surfaces of the first to third scattering layers SCL1, SCL2, and SCL3 and greater than those of upper surfaces of the first and second light-conversion layers QD1 and QD2.

Here, the upper surface of each component may be one surface in a direction in which light is emitted. The upper surface of each component disposed on the protective layer 116 may be a surface opposite to a lower surface facing the protective layer 116.

Here, the height of the upper surface of each component disposed on the protective layer 116 may be a height from the substrate 101 or a height from the protective layer 116.

Depending on the thickness of the black matrix BM and a height of the upper surface of the black matrix BM, the matrix openings MOP (MOP1, MOP2, MOP3) may be formed to expose the upper insulating film 117 disposed on the scattering layers SCL (SCL1, SCL2, and SCL3) and the light-conversion layers QD (QD1 and QD2).

For example, in the first sub-pixel SP1, a first matrix opening MOP1 may expose the upper insulating film 117. In the second sub-pixel SP2, a second matrix opening MOP2 may expose the upper insulating film 117. In the third sub-pixel SP3, a third matrix opening MOP3 may expose the upper insulating film 117.

In some implementations, the matrix openings MOP (MOP1, MOP2, MOP3) may be larger than the bank openings BOP (BOP1, BOP2, BOP3). The first to third matrix openings MOP1, MOP2, and MOP3 may overlap the first to third bank openings BOP1, BOP2, and BOP3 in the thickness direction (third direction DR3), respectively.

For example, the first matrix opening MOP1 may be larger than the first bank opening BOP1, and the first matrix opening MOP1 may overlap the entire area of the first bank opening BOP1 in the thickness direction (third direction DR3). The second matrix opening MOP2 may be larger than the second bank opening BOP2, and the second matrix opening MOP2 may overlap the entire area of the second bank opening BOP2 in the thickness direction (third direction DR3). The third matrix opening MOP3 may be larger than the third bank opening BOP3, and the third matrix opening MOP3 may overlap the entire area of the third bank opening BOP3 in the thickness direction (third direction DR3).

Sidewalls of the first bank opening BOP1 may protrude further inward than sidewalls of the first matrix opening MOP1, sidewalls of the second bank opening BOP2 may protrude further inward than sidewalls of the second matrix opening MOP2, and sidewalls of the third bank opening BOP3 may protrude further inward than sidewalls of the third matrix opening MOP3.

The black matrix BM may protrude further than a color filter layer CF in the thickness direction (third direction DR3). As such, the height of the upper surface of the black matrix BM may be greater than the height of an upper surface of the color filter layer CF from the substrate 101.

Accordingly, the color mixing between adjacent sub-pixels (SP1, SP2, and SP3) can be mitigated more smoothly.

The color filter layers CF (CF1, CF2, CF3) may be disposed on the upper insulating film 117. The color filter layers CF (CF1, CF2, CF3) may be disposed inside the matrix openings MOP and may be in direct contact with the upper insulating film 117.

The color filter layers CF (CF1, CF2, CF3) may be in direct contact with the side surfaces of the black matrix BM. The color filter layers CF (CF1, CF2, CF3) may be in direct contact with the black matrix BM that separates the color filter layers CF (CF1, CF2, CF3) disposed in adjacent sub-pixels (SP1, SP2, SP3). The color filter layers CF (CF1, CF2, CF3) may be in direct contact with the black matrix BM that protrudes further than the color filter layers CF (CF1, CF2, CF3) in the thickness direction (third direction DR3).

The first color filter CF1 may be disposed in the first sub-pixel SP1, the second color filter CF2 may be disposed in the second sub-pixel SP2, and the third color filter CF3 may be disposed in the third sub-pixel SP3. The first color filter layer CF1 may be disposed inside the first matrix opening MOP1, the second color filter layer CF2 may be disposed inside the second matrix opening MOP2, and the third color filter layer CF3 may be disposed inside the third matrix opening MOP3.

Each of the first to third color filter layers CF1, CF2, and CF3 may transmit only light of a wavelength corresponding to the color of the light emitted from each of the sub-pixels (SP1, SP2, and SP3). For example, when the first sub-pixel SP1 emits red light, the second sub-pixel SP2 emits green light, the third sub-pixel SP3 emits blue light, and the light-emitting element 120 emits blue light, the first color filter layer CF1 may transmit only light of a wavelength corresponding to red, the second color filter layer CF2 may transmit only light of a wavelength corresponding to green, and the third color filter layer CF3 may transmit only light of a wavelength corresponding to blue.

The first to third color filter layers CF1, CF2, and CF3 may be separated and spaced apart from each other by the black matrix BM. That is, the black matrix BM may be disposed between the first to third color filter layers CF1, CF2, and CF3.

Since the color filter layer CF is in direct contact with the upper insulating film 117, it is possible to minimize the gaps between the scattering layers SCL (SCL1, SCL2, SCL3) or the light-conversion layers QD (QD1, QD2) and the color filter layer CF. Accordingly, it is possible to minimize light passing through the scattering layers SCL (SCL1, SCL2, SCL3) and the light-conversion layers QD (QD1, QD2) from leaking into adjacent sub-pixels SP1, SP2, and SP3) before passing through the color filter layer CF.

Furthermore, it is possible to minimize the color mixing between adjacent sub-pixels (SP1, SP2, SP3) and improve color reproducibility, and the display apparatus 10 may be driven at a low power level, thereby reducing power consumption. In addition, the thickness of the display apparatus 10 can be reduced.

Since the color filter layer CF is in direct contact with the upper insulating film 117, even when the matrix openings MOP (MOP1, MOP2, MOP3) are larger than the bank openings BOP (BOP1, BOP2, BOP3), the color mixing between adjacent sub-pixels (SP1, SP2, and SP3) can be prevented more smoothly. In addition, since the matrix openings MOP (MOP1, MOP2, MOP3) are larger than the bank openings BOP (BOP1, BOP2, BOP3), the luminance of the sub-pixels (SP1, SP2, and SP3) can be improved. That is, it is possible to prevent the color mixing between adjacent sub-pixels (SP1, SP2, and SP3) and minimize the reduction in luminance or improve luminance.

The present specification describes the black matrix BM including black pigments and dyes, etc., but various implementations of the present specification are not limited thereto. For example, the black matrix BM may be formed such that at least some areas of the first to third color filter layers CF1, CF2, and CF3 that transmit light of different colors are formed to be thickened in the thickness direction (third direction DR3).

In this case, edge areas of the first to third color filter layers CF1, CF2, and CF3 may be disposed around the boundaries of the sub-pixels (SP1, SP2, and SP3), respectively. That is, the edge areas of the first to third color filter layers CF1, CF2, and CF3 may be disposed in the areas in which the scattering layers SCL (SCL1, SCL2, SCL3) are spaced apart from each other and in the areas in which the light-conversion layers QD (QD1, QD2) are spaced apart from each other. In this case, the edge areas of the first to third color filter layers CF1, CF2, and CF3 disposed around the boundaries of the sub-pixels (SP1, SP2, and SP3) may have a thickness greater than those of the remaining areas.

The black matrix BM may separate the scattering layers SCL (SCL1, SCL2, SCL3), the light-conversion layers QD (QD1, QD2), and the color filter layers CF (CF1, CF2, CF3), which are disposed in adjacent sub-pixels (SP1, SP2, and SP3). The black matrix BM may be disposed between the scattering layers SCL (SCL1, SCL2, SCL3), the light-conversion layers QD (QD1, QD2), and the color filter layers CF (CF1, CF2, CF3), which are disposed in adjacent sub-pixels (SP1, SP2, and SP3).

For example, the black matrix BM may be integrally formed to collectively separate the scattering layers SCL (SCL1, SCL2, SCL3), the light-conversion layers QD (QD1, QD2), and the color filter layers CF (CF1, CF2, CF3), which are disposed in adjacent sub-pixels (SP1, SP2, SP3), but is not limited thereto.

Since the black matrix BM is integrally formed to cover side surfaces of the scattering layers SCL (SCL1, SCL2, SCL3), side surfaces of the light-conversion layers QD (QD1, QD2), and side surfaces of the color filter layers CF (CF1, CF2, CF3), it is possible to minimize light leakage from the middle of one of the scattering layers SCL (SCL1, SCL2, SCL3), the light-conversion layers QD (QD1, QD2), and the color filter layers CF (CF1, CF2, CF3) to the adjacent sub-pixels (SP1, SP2, and SP3).

Accordingly, light passing through only at least some of the scattering layers SCL (SCL1, SCL2, SCL3), the light-conversion layers QD (QD1, QD2), and the color filter layers CF (CF1, CF2, CF3) can be minimized from leaking into adjacent sub-pixels (SP1, SP2, and SP3). As such, the color mixing between adjacent sub-pixels (SP1, SP2, and SP3) can be prevented more smoothly.

The overcoat layer OC may be disposed on the color filter layer CF. The overcoat layer OC may cover both the color filter layer CF and the black matrix BM.

Hereinafter, an example of a method of manufacturing the display apparatus 10 according to one implementation will be described. While describing the method of manufacturing the display apparatus 10 according to one implementation, the descriptions of parts already described in FIGS. 1 to 4 will be briefly provided or omitted.

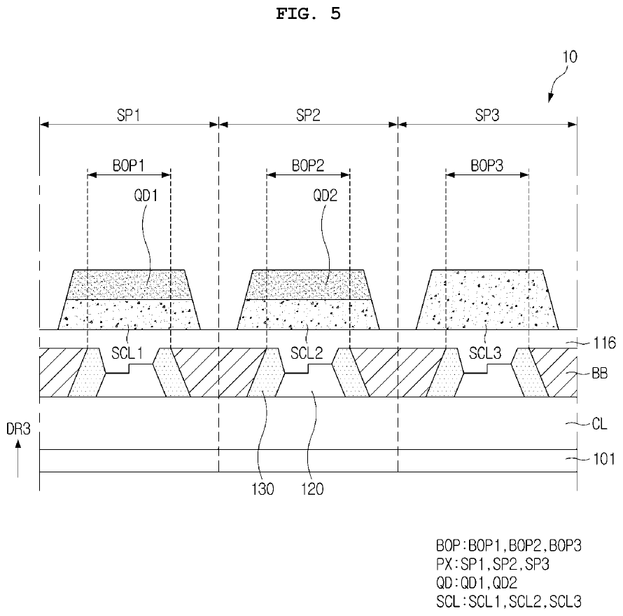

FIGS. 5 to 7 are views illustrating each operation of a process of manufacturing the display apparatus according to one implementation.

First, referring to FIG. 5, the circuit layer CL is formed on the substrate 101. Next, the light-emitting element 120 is disposed on the circuit layer CL. The light-emitting element 120 may be transferred onto the circuit layer CL, particularly, the adhesive layer AD, and disposed in each of the sub-pixels (SP1, SP2, and SP3).

After the light-emitting elements 120 are transferred, the diffusion layers 130 are patterned and disposed around the light-emitting element 120, and the banks BB are formed between the patterned diffusion layers 130. By arranging the diffusion layers 130 and forming the banks BB, side surfaces of the bank BB may be formed in an inverse-taper shape.

As the banks BB are patterned, the bank openings BOP (BOP1, BOP2, BOP3) may be formed.

The protective layer 116 may be formed on the banks BB. The protective layer 116 may cover all of the banks BB, the diffusion layers 130, and the light-emitting elements 120.

Next, the scattering layer SCL and the light-conversion layer QD may be formed on the protective layer 116. The scattering layer SCL and the light-conversion layer QD may be patterned and disposed in each of the sub-pixels (SP1, SP2, and SP3). The scattering layer SCL and the light-conversion layer QD disposed in each of the sub-pixels (SP1, SP2, and SP3) may be separated and spaced apart from each other, but are not limited thereto.

The scattering layer SCL and the light-conversion layer QD may be patterned by a digital lithography tool (DLT) or the like, but are not limited thereto.

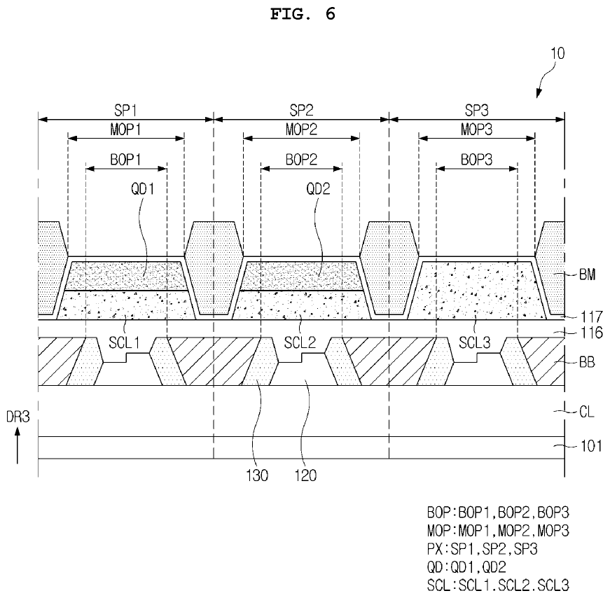

Next, referring to FIG. 6, the upper insulating film 117 may be formed on the scattering layer SCL and the light-conversion layer QD, which are patterned. The upper insulating film 117 may cover the upper and side surfaces of the scattering layer SCL and the light-conversion layer QD. The upper insulating film 117 may also be disposed between the scattering layer SCL and the light-conversion layer QD that are disposed in adjacent sub-pixels (SP1, SP2, and SP3).

Next, the black matrix BM may be formed on the upper insulating film 117. The black matrix BM may be patterned and disposed at the boundaries and peripheries of the sub-pixels (SP1, SP2, and SP3).

The black matrix BM may be disposed between the scattering layer SCL and the light-conversion layer QD that are disposed in adjacent sub-pixels (SP1, SP2, and SP3). The black matrix BM may fill the space between the scattering layer SCL and the light-conversion layer QD that are disposed in adjacent sub-pixels (SP1, SP2, and SP3). The black matrix BM may fill the space between the scattering layer SCL and the light-conversion layer QD and protrude further than the upper insulating film 117 in the thickness direction (third direction DR3).

The black matrix BM may include the matrix openings MOP (MOP1, MOP2, MOP3) that expose the upper insulating film 117 through patterning. The matrix openings MOP (MOP1, MOP2, MOP3) may be formed by passing through the black matrix BM in the thickness direction (third direction DR3). The matrix openings MOP (MOP1, MOP2, MOP3) may be disposed in the sub-pixels (SP1, SP2, and SP3), respectively, and may expose at least a portion of the upper insulating film 117 disposed on the scattering layer SCL and/or the light-conversion layer QD.

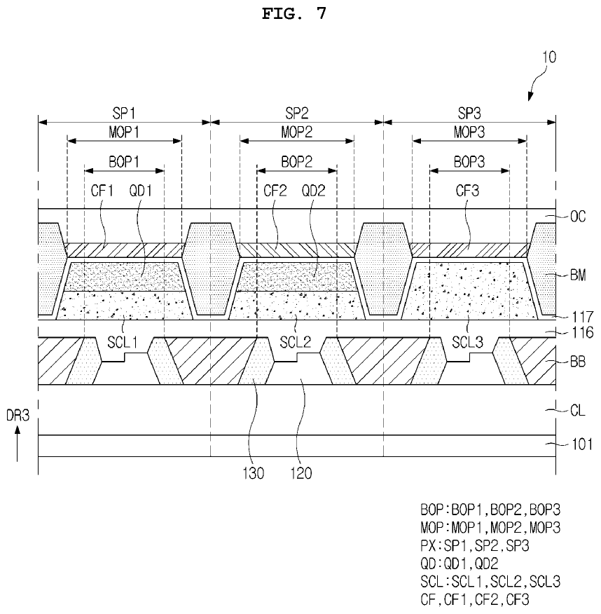

Next, referring to FIG. 7, the color filter layers CF (CF1, CF2, CF3) that transmit the colors corresponding to the colors emitted from the sub-pixels (SP1, SP2, and SP3) are disposed in the sub-pixels (SP1, SP2, and SP3), respectively. The color filter layers CF (CF1, CF2, CF3) may be patterned and formed in the sub-pixels (SP1, SP2, and SP3), respectively.

The color filter layers CF (CF1, CF2, CF3) may be disposed inside the matrix openings MOP (MOP1, MOP2, MOP3) and may be in direct contact with the upper insulating film 117 exposed by the matrix openings MOP (MOP1, MOP2, MOP3).

The black matrix BM may be integrally formed, disposed between the scattering layers SCL (SCL1, SCL2, SCL3), the light-conversion layers QD (QD1, QD2), and the color filter layers CF (CF1, CF2, CF3), which are disposed in adjacent sub-pixels (SP1, SP2, and SP3), and may separate the corresponding components.

Hereinafter, other implementations of the present specification will be described. For contents that are substantially the same as those described with reference to FIGS. 1 to 7 among components included in other implementations, the same reference numerals are given, and overlapping contents may be omitted or briefly described.

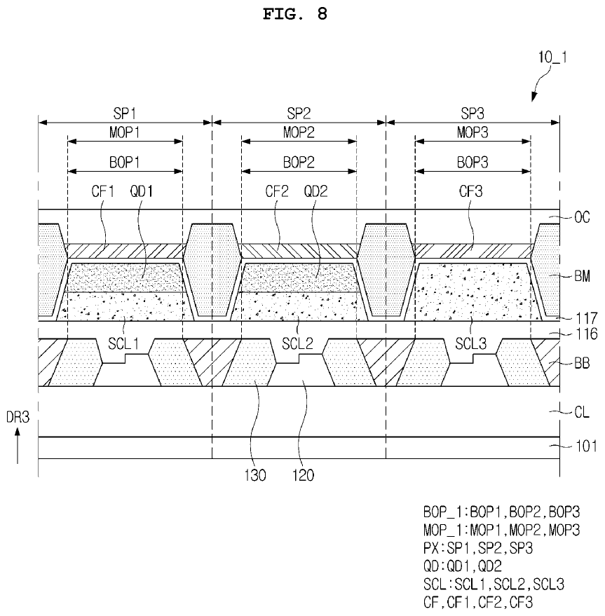

FIG. 8 is a cross-sectional view of a display apparatus according to another implementation taken along a line similar to line A-A′ in FIG. 2.

Referring to FIG. 8, a display apparatus 10_1 according to the present implementation may include bank openings BOP_1 (BOP1, BOP2, BOP3) defined by the bank BB and matrix openings MOP_1 (MOP1, MOP2, MOP3) defined by the black matrix BM. Sidewalls of the bank openings BOP_1 (BOP1, BOP2, BOP3) and sidewalls of the matrix openings MOP_1 (MOP1, MOP2, MOP3) may be aligned.

That is, the bank openings BOP_1 (BOP1, BOP2, BOP3) and the matrix openings MOP_1 (MOP1, MOP2, MOP3) may have the same planar size. The entire area of the bank openings BOP_1 (BOP1, BOP2, BOP3) and the entire area of the matrix openings MOP_1 (MOP1, MOP2, MOP3) may overlap in the thickness direction (third direction DR3).

Even in this case, since the color filter layer CF is in direct contact with the upper insulating film 117, it is possible to prevent the color mixing between adjacent sub-pixels (SP1, SP2, and SP3) and minimize the reduction in luminance or improve luminance.

A display apparatus according to various implementations of the present specification may be described as follows.

According to various implementations of the present specification, there is provided a display apparatus including a substrate, a light-emitting element disposed on the substrate, a light-conversion layer disposed on the light-emitting element, an upper insulating film disposed on the light-conversion layer, and a color filter layer disposed on the upper insulating film, wherein the color filter layer is in direct contact with the upper insulating film.

According to various implementations of the present specification, the display apparatus may further comprise a bank disposed on the substrate, wherein the bank may define a bank opening, and the light-emitting element may be disposed inside the bank opening.

According to various implementations of the present specification, the display apparatus may further comprise a diffusion layer disposed on the substrate, wherein the diffusion layer may surround the light-emitting element, and the bank may surround the diffusion layer and the light-emitting element.

According to various implementations of the present specification, the light-emitting element may be a light-emitting diode including an inorganic film for emitting light.

According to various implementations of the present specification, the display apparatus may further include a black matrix which is disposed on the upper insulating film and defines a matrix opening exposing a portion of the upper insulating film, in which the color filter layer may be disposed inside the matrix opening.

According to various implementations of the present specification, the display apparatus may further include a first sub-pixel and a second sub-pixel which are disposed on the substrate and emit light of different colors, in which the black matrix may be disposed at a boundary and periphery of the first sub-pixel and the second sub-pixel, the light-conversion layer may be separated and may include a first light-conversion layer disposed in the first sub-pixel and a second light-conversion layer disposed in the second sub-pixel, and the upper insulating film and the black matrix may be disposed between the first light-conversion layer and the second light-conversion layer.

According to various implementations of the present specification, the color filter layer may be separated and may include a first color filter layer disposed in the first sub-pixel and a second color filter layer disposed in the second sub-pixel, and the black matrix may be disposed between the first color filter layer and the second color filter layer.

According to various implementations of the present specification, the black matrix may be integrally formed, disposed between the first light-conversion layer and the second light-conversion layer and between the first color filter layer and the second color filter layer, and may protrude further than the color filter layer in a thickness direction.

According to various implementations of the present specification, the display apparatus may further comprise a protective layer disposed on the light-emitting layer, wherein the first light-conversion layer and the second light-conversion layer may expose a portion of a protective layer therebetween, and the upper insulating film may be in direct contact with the portion of the protective layer between the first light-conversion layer and the second light-conversion layer.

According to various implementations of the present specification, sidewalls of the bank opening may protrude further inward than sidewalls of the matrix opening.

According to various implementations of the present specification, the sidewalls of the bank opening and the sidewalls of the matrix opening may be aligned.

According to various implementations of the present specification, the color filter layer may be in direct contact with the black matrix.

According to various implementations of the present specification, the bank and the light-emitting element may be disposed on the same layer.

According to various implementations of the present specification, the display apparatus may further comprise a circuit layer disposed on the substrate, wherein the circuit layer may include a driving transistor disposed on the substrate, a planarization layer disposed on the driving transistor, and an adhesive layer disposed on the planarization layer, and the bank and the light-emitting element may be disposed on the adhesive layer and may be in direct contact with the adhesive layer.

According to various implementations of the present specification, an edge area of at least one of the first and second color filter layers may be disposed in an area in which the first and second light-conversion layers are spaced apart from each other and have a greater thickness than the remaining area thereof.

According to various implementations of the present specification, the black matrix may be integrally formed to cover side surfaces of the light-conversion layer and side surfaces of the color filter layer.

According to various implementations of the present specification, there is provided a display apparatus including a substrate on which a first sub-pixel and a second sub-pixel are disposed, a light-emitting element disposed in each of the first sub-pixel and the second sub-pixel on the substrate, a light-conversion layer disposed on the light-emitting element and including a first light-conversion layer disposed in the first sub-pixel and a second light-conversion layer disposed in the second sub-pixel, an upper insulating film disposed on the light-conversion layer, a color filter layer disposed on the upper insulating film and including a first color filter layer disposed in the first sub-pixel and a second color filter layer disposed in the second sub-pixel, and a black matrix which is disposed on the upper insulating film, separates the first light-conversion layer from the second light-conversion layer, and separates the first color filter layer from the second color filter layer.

According to various implementations of the present specification, the black matrix may be integrally formed, disposed between the first light-conversion layer and the second light-conversion layer and between the first color filter layer and the second color filter layer, and may protrude further than the color filter layer in a thickness direction.

According to various implementations of the present specification, the black matrix may define a matrix opening exposing a portion of the upper insulating film disposed on the light-conversion layer, and the color filter layer may be disposed in the matrix opening.

According to various implementations of the present specification, the color filter layer may be in direct contact with the black matrix.

According to various implementations of the present specification, the color filter layer may be in direct contact with the portion of the upper insulating film exposed by the matrix opening.

According to various implementations of the present specification, the display apparatus may further include a protective layer disposed between the light-emitting element and the light-conversion layer, in which the first light-conversion layer and the second light-conversion layer may expose a portion of the protective layer therebetween, and the upper insulating film may be in direct contact with the portion of the protective layer between the first light-conversion layer and the second light-conversion layer.

Although various implementations have been described above with reference to the accompanying drawings, those skilled in the art to which the present specification pertains will be able to understand that the above-described technical configuration can be carried out in other specific forms without changing the technical spirit or essential features thereof. Accordingly, it should be understood that the above-described implementations are illustrative and not restrictive in all respects. In addition, the scope of various implementations is determined by the appended claims rather than detailed description. In addition, the meaning and scope of the claims and all changed or modified forms derived from the equivalent concept thereof should be construed as being included in the scope of various implementations.

What is claimed is:

1. A display apparatus comprising:
a substrate;
a light emitting element disposed on the substrate;
a light-conversion layer disposed on the light emitting element;
an upper insulating film disposed on the light-conversion layer; and
a color filter layer disposed on the upper insulating film,
wherein the color filter layer is in direct contact with the upper insulating film.

2. The display apparatus of claim 1, further comprising a bank disposed on the substrate, wherein the bank includes a bank opening that penetrates through the bank, and
wherein the light emitting element is disposed inside the bank opening.

3. The display apparatus of claim 2, further comprising a diffusion layer disposed on the substrate, wherein the diffusion layer surrounds the light emitting element, and
wherein the bank surrounds the diffusion layer and the light emitting element.

4. The display apparatus of claim 3, wherein the light emitting element is a light emitting diode including an inorganic film configured to emit light.

5. The display apparatus of claim 2, further comprising a black matrix which is disposed on the upper insulating film and includes a matrix opening that penetrates through the upper insulating film and exposes a portion of the upper insulating film,
wherein the color filter layer is disposed inside the matrix opening.

6. The display apparatus of claim 5, further comprising a first sub-pixel and a second sub-pixel which are disposed on the substrate and are configured to emit light of different colors,
wherein the black matrix is disposed at a boundary and at a periphery of the first sub-pixel and the second sub-pixel,
wherein the light-conversion layer includes a first light-conversion layer disposed in the first sub-pixel and a second light-conversion layer disposed in the second sub-pixel, with the first light-conversion layer and the second light-conversion layer spaced apart from each other, and
wherein the upper insulating film and the black matrix are disposed between the first light-conversion layer and the second light-conversion layer.

7. The display apparatus of claim 6, wherein the color filter layer includes a first color filter layer disposed in the first sub-pixel and a second color filter layer disposed in the second sub-pixel, with the first color filter layer and the second color filter layer spaced apart from each other, and
wherein the black matrix is disposed between the first color filter layer and the second color filter layer.

8. The display apparatus of claim 7, wherein the black matrix is integrally formed, is disposed between the first light-conversion layer and the second light-conversion layer and between the first color filter layer and the second color filter layer, and protrudes further than the color filter layer in a thickness direction.

9. The display apparatus of claim 6, further comprising a protective layer disposed on the light emitting element, wherein a space between the first light-conversion layer and the second light-conversion layer exposes a portion of the protective layer, and
wherein the upper insulating film is in direct contact with the portion of the protective layer between the first light-conversion layer and the second light-conversion layer.

10. The display apparatus of claim 5, wherein
sidewalls of the bank opening protrude further inward than sidewalls of the matrix opening.

11. The display apparatus of claim 5, wherein
sidewalls of the bank opening and sidewalls of the matrix opening are aligned.

12. The display apparatus of claim 5, wherein the color filter layer is in direct contact with the black matrix.

13. The display apparatus of claim 2, wherein the bank and the light emitting element are disposed on a same layer.

14. The display apparatus of claim 13, further comprising a circuit layer disposed on the substrate, wherein the circuit layer includes a driving transistor disposed on the substrate, a planarization layer disposed on the driving transistor, and an adhesive layer disposed on the planarization layer, and
wherein the bank and the light emitting element are disposed on the adhesive layer and are in direct contact with the adhesive layer.

15. The display apparatus of claim 7, wherein an edge area of at least one of the first color filter layer or the second color filter layer is disposed in an area in which the first light-conversion layer and the second light-conversion layer are spaced apart from each other, and
wherein the edge area of at the least one of the first color filter layer or the second color filter layer has a greater thickness than a remaining area thereof.

16. The display apparatus of claim 7, wherein the black matrix is integrally formed to cover side surfaces of the light-conversion layer and side surfaces of the color filter layer.

17. A display apparatus comprising:
a substrate on which a first sub-pixel and a second sub-pixel are disposed;
a plurality of light emitting elements including a first light emitting element disposed in the first sub-pixel and a second light emitting element disposed in the second sub-pixel on the substrate;
a light-conversion layer disposed on the plurality of light emitting elements and including a first light-conversion layer disposed in the first sub-pixel and a second light-conversion layer disposed in the second sub-pixel;
an upper insulating film disposed on the light-conversion layer;
a color filter layer disposed on the upper insulating film and including a first color filter layer disposed in the first sub-pixel and a second color filter layer disposed in the second sub-pixel; and
a black matrix which is disposed on the upper insulating film, separates the first light-conversion layer from the second light-conversion layer, and separates the first color filter layer from the second color filter layer.

18. The display apparatus of claim 17, wherein the black matrix is integrally formed, is disposed between the first light-conversion layer and the second light-conversion layer and between the first color filter layer and the second color filter layer, and protrudes further than the color filter layer in a thickness direction.

19. The display apparatus of claim 17, wherein the black matrix includes a matrix opening that penetrates through the black matrix and exposes a portion of the upper insulating film disposed on the light-conversion layer, and
wherein the color filter layer is disposed inside the matrix opening.

20. The display apparatus of claim 19, wherein the color filter layer is in direct contact with the black matrix.

21. The display apparatus of claim 19, wherein the color filter layer is in direct contact with the portion of the upper insulating film exposed by the matrix opening.

22. The display apparatus of claim 17, further comprising a protective layer disposed between the plurality of light emitting elements and the light-conversion layer,
wherein a space between the first light-conversion layer and the second light-conversion layer exposes a portion of the protective layer, and
wherein the upper insulating film is in direct contact with the portion of the protective layer between the first light-conversion layer and the second light-conversion layer.
